(19) United States
(12) Patent Application Publication
(10) Pub. No.: US 2014/0350875 A1
(43) Pub. Date: Nov. 27, 2014

(54) RELAXATION MODEL IN REAL-TIME ESTIMATION OF STATE-OF-CHARGE IN LITHIUM POLYMER BATTERIES

(71) Applicants: Scott Allen Mullin, San Leandro, CA (US); Albert Aumentado, El Cerrito, CA (US); Mohit Singh, Berkeley, CA (US)

(72) Inventors: Scott Allen Mullin, San Leandro, CA (US); Albert Aumentado, El Cerrito, CA (US); Mohit Singh, Berkeley, CA (US)

(21) Appl. No.: 13/940,176

(22) Filed: Jul. 11, 2013

Related U.S. Application Data
(60) Provisional application No. 61/827,712, filed on May 27, 2013.

(51) Int. Cl. G01R 31/36

(52) U.S. Cl. CPC G01R 31/3648
USPC 702/63

(57) ABSTRACT

Relaxation time constants give valuable information about a lithium polymer battery cell's state-of-charge. Moreover, determination of these time constants can be performed in real time by fitting exponential functions to transient voltage or current patterns.

### CROSS-REFERENCE

This application claims priority to U.S. Provisional Patent Application Ser. No. 61/827,712, filed on May 27, 2013, which is entirely incorporated herein by reference.

### STATEMENT OF GOVERNMENT SUPPORT

The invention described and claimed herein was made in part utilizing funds supplied by the U.S. Department of Energy under Contract No. DE-EE0005449. The Government has certain rights in this invention.

### BACKGROUND OF THE INVENTION

### Field of the Invention

This invention relates generally to methods for determining state of charge for secondary batteries, and, more specifically, to using battery relaxation parameters in real time to determine same.

Real-time estimation of battery relaxation parameters can be used to provide additional information about a cell's state-of-charge and state-of-health.

State of charge (SOC) is the equivalent of a fuel gauge for the battery pack in a battery electric vehicle (BEV), hybrid vehicle (HEV), or plug-in hybrid electric vehicle (PHEV). SOC is usually expressed as a percentage of full charge (e.g., 0%=empty; 100%=full). An alternate form of the same measure is the depth of discharge (DoD), the inverse of SOC (e.g., 100%=empty; 0%=full). SOC is normally used when discussing the current state of a battery in use, while DoD is most often used when discussing the capacity utilization of a cell during performance rating or cycle life testing.

State-of-charge (SOC) and state-of-health (SOH) are important parameters for monitoring and controlling battery cells, but they can be difficult to determine in many cases. SOH is typically estimated by tracking a cell's accessible capacity.

For battery chemistries where the open-circuit voltage (OCV) decreases continuously during discharge, there is a reasonable correlation between the open-circuit voltage and the SOC. When a cell is either charging or discharging (that is, under operation instead of in an open-circuit condition), the passing of current causes a deviation from the open-circuit voltage that depends on the sign and magnitude of the current. Charging increases the voltage above the cell's OCV and discharging decreases the voltage below the cell's OCV. When current is removed and a cell is allowed to relax, the cell voltage can return to the OCV. Deviations from OCV under load are caused by several phenomena, including electrochemical effects such as electrolyte polarization and interfacial polarization. In the simplest operation scenarios, the OCV can be determined once a sufficient period of relaxation time has passed. In chemistries where the OCV changes significantly with SOC, and in which the deviations from OCV under load conditions are relatively small, voltages under load can be used as a close proxy for the OCV. Thus, the voltage along with the amount of current passed into and out of the cell can be used to make an estimate of the SOC. For such battery chemistries, these estimates are often good enough for most purposes.

But for some other battery chemistries, the open-circuit voltage does not decrease continuously during discharge. For example, in a cell with a lithium metal anode and a LiFePO₄ cathode, the open-circuit voltage decreases at the very beginning of discharge and then remains stable throughout most of the discharge until it finally drops at the end. As the cell continues to discharge, the SOC decreases whereas the open-circuit voltage remains nearly constant. This relatively flat open-circuit voltage curve is not useful in trying to determine the SOC of such a cell.

Additional factors that can undermine SOC determination from voltage monitoring may include measurement uncertainty and cell polarization.

Another method, known as current accounting or Coulomb counting, calculates the SOC by measuring the battery current and integrating it over time. Problems with this method include long-term drift, lack of a reference point, and, uncertainties about a cell's total accessible capacity (which changes as the cell ages) and operation history. Only fully-charged or fully-discharged cells have well-defined SOCs (100% and 0%, respectively).

SOH determination is similarly convoluted—accurate capacity determination is difficult in dynamic usage scenarios due to errors in Coulomb counting. These problems are particularly compounded in lithium-polymer cells in which transport limitations give rise to significant cell polarization, which obscures voltage end-point determination under load.

Some methods of SOC determination involve fitting complicated resistor-capacitor (RC) circuit models to a priori tests in order to model dynamic cell behavior. However, those methods are very complicated, computationally intensive, and are indirect, all of which can contribute to errors and cost. Moreover, such methods are set up in advance, and are not used to predict real-time status indicators.

What is needed is a simple, direct, accurate method to determine the SOC for rechargeable batteries.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a plot of voltage as a function of SOC that was generated by allowing a cell to relax to its equilibrium value after discharging to various SOC values.

FIG. 2 is a plot of voltage and current as a function of time and shows changes that occur with constant current discharges and rest steps at each 10% decrease in cell capacity.

FIG. 3 is a plot of open-circuit voltage as a function of log time that was generated using data extracted from FIG. 2.

FIG. 4 is a plot that shows f(Γ) as a function of log Γ at various SOCs according to Equation 2 (shown below) that was generated using data extracted from FIG. 3.

FIG. 5 is a plot that shows f(Γ)-weighted-average values of Γ as a function of SOC that was generated using data extracted from FIG. 4.

FIG. 6 is a plot that shows values of time constants τ₁ and τ₂, each as a function of SOC, for the first 10 seconds of the curves shown in the resting case of FIG. 3.

FIG. 7 is a plot of voltage and current as a function of time and shows changes that occur during a current discharge that has periodic high-current discharge pulses at each 10% decrease in cell capacity.

FIG. 8 is a plot that shows values of time constants τ₁ and τ₂, each as a function of SOC, for the first 10 seconds of the curves shown in the non-resting case in FIG. 7.

FIG. 9 is a plot of open-circuit voltage as a function of log time during various rest stages, extracted from cycling data for a cell over the course of over 450 cycles.

FIG. 10 is a plot that shows time constants as extracted from the curves in FIG. 7.

FIG. 11 shows a computer system that is programmed or otherwise configured to determine the state of charge of a battery.

### SUMMARY

A method of determining the state of charge for a battery cell is disclosed. The method involves the steps of measuring voltage and current as a function of time while the battery cell is operating; recording the voltage as a function of time over periods in which the current, expressed in terms of C-rate, is stable to within +/−0.01 C; fitting the recorded voltage as a function of time to a pre-defined function that has three or more fit parameters; extracting the fit parameters; and comparing the fit parameters to a previously-populated look-up table that correlates the fit parameters to state-of-charge values to determine the state of charge. In some arrangements, the method is performed in real time on an operating battery.

In one embodiment of the invention, the method is used for a battery cell that has a lithium metal anode, a lithium iron phosphate cathode, and a polymer electrolyte separator.

In one arrangement, the pre-defined function has a single exponential term and has the form:

$$OCV ( {t}_{fit} ) = {k}_{0} + {k}_{1} {e}^{- \frac{t}{{τ}_{1}}} .$$

In another arrangement, the pre-defined function has two exponential terms and has the form:

$$OCV ( {t}_{fit} ) = {k}_{0} + {k}_{1} {e}^{- \frac{t}{{τ}_{1}}} + {k}_{2} {e}^{- \frac{t}{{τ}_{2}}} .$$

### DETAILED DESCRIPTION

The preferred embodiments are illustrated in the context of determining SOC for Li metal-LiFePO₄ battery cells. The skilled artisan will readily appreciate, however, that the materials and methods disclosed herein will have application with a number of other battery chemistries where determination of SOC using current methods is difficult, particularly where simplicity and real-time measurement are important.

These and other objects and advantages of the present invention will become more fully apparent from the following description taken in conjunction with the accompanying drawings.

All publications referred to herein are incorporated by reference in their entirety for all purposes as if fully set forth herein.

The current/voltage responses of lithium polymer batteries are complicated by numerous chemical/physical processes. A fully-relaxed cell in the open-circuit condition has an open-circuit voltage (OCV) that is a function of the cell's state-of-charge (SOC). (State of charge (SOC) and depth-of-discharge (DOD) have an inverse relationship, SOC=1-DOD.) OCV can be plotted as a function of log time to make an OCV curve. The OCV curve arises from the thermodynamic potentials of each electrode at a given lithium stoichiometry and depends on the particular electrode materials used in the cell and their relative proportions. During operation, each measured potential is a function of the cell's previous operating history and the instantaneous current draw. This is commonly expressed as a deviation from the OCV curve at each SOC. These deviations from OCV can be caused by many factors, including, but not limited to, resistive cell components, interfacial polarization at each electrode, and polarization of the electrolyte (both in the separator and within any electrolyte-containing electrodes). Furthermore, during operation, electrodes tend to distribute charge unevenly across their thickness such that the lithium stoichiometry varies from point-to-point within the electrode. Uneven stoichiometric distributions within electrodes tend to relax towards uniformity over time, which manifests as an additional time-dependent contribution to the measured terminal voltage of the cell.

Currently, there are models that try to predict a cell's voltage over time under various load conditions, or, inversely, to predict a cell's state-of-charge from a measured terminal voltage. The complexity and nature of such models varies widely. In some scenarios, such models are built from first-principle chemical models that involve numerous, coupled partial-differential equations and physical and geometric parameters. In other scenarios, the cells are assumed to behave in a simple manner and are modeled as an RC (resistance, capacitance) circuit. Such models are very complex and are difficult to compute in real time; computations can take as long as days. Most models are seeded with dynamic response parameters measured, calculated, fitted, or otherwise defined prior to their implementation in actively running devices. Such models are not designed to respond when dynamic response parameters change in unpredictable ways.

A new model for measuring SOC and SOH based on real-time determination of physical parameters in an operating cell has been developed based on recording cell voltage over time.

Electrolyte relaxation in polarized electrochemical cells can be rigorously modeled using Equation 1.

$$OCV ( {t}_{fit} ) = {k}_{0} + {k}_{1} {e}^{- \frac{t}{{τ}_{1}}} \qquad [ 1 ]$$

where τ₁, k₀, and k₁ are constants, t is elapsed time and t_{fit} refers specifically to the relaxation time period over which the fit is performed. This simple framework was derived for restricted diffusion experiments, which have been made under a specific set of conditions:
cells are symmetric (having two identical electrodes in a planar configuration);
cells are well-polarized initially;
thermodynamic potential across battery terminals is zero;
cell geometry is one-dimensional;
electrolyte thickness (L) is well-known; and
OCV is monitored without applied current for a substantial period of time (tᵣₑₛₜ) such that Dtᵣₑₛₜ/L²>0.05, where D is the electrolyte salt diffusion coefficient.

Under these conditions, an electrolyte relaxation period, without any current passage, can be closely fitted to Equation 1. Equation 1 has a physical basis, as given by the expression

$$τ = \frac{{π}^{2} D}{{L}^{2}} ,$$

where D is the electrolyte salt diffusion coefficient in the electrolyte. This physical basis distinguishes this method from empirical models such as RC circuit fitting. The fitting region is bounded by the time parameters t_{fit|0} and t_{fit|final} where t_{fit|0} is the time at the start of the fitting region and t_{fit|final} is the time at the end of the fitting region. In practice, tᵣₑₛₜ is offset by t_{fit|0} such that the first point on tᵣₑₛₜ is zero, and t_{fit|final} is the total elapsed time during the fitting region. The value of OCV at time tᵣₑₛₜ=t_{fit|0} is k₁. The value of OCV at equilibrium is k₀, which is defined as zero for symmetric electrodes, but actually has a small, non-zero value due to complication such as measurement bias, thermal noise and processing differences in electrodes. In the most rigorous applications, the onset of the fitting regime may begin after tens of seconds to tens of minutes of rest, and the fitting region may be several minutes to several hours. This method describes the physical behavior so well that it can give diffusion coefficients accurate to within 0.1%.

The rigorously-defined conditions described above are not generally thought to be applicable for determining relaxation behavior in battery systems due to a number of complications because:
electrodes are not symmetric;
thermodynamic potential across battery terminals is nonzero;
battery cell geometry may not be reducible to 1-dimension; and
batteries exhibit multiple concurrent voltage relaxation phenomena.

Further academic research has shown that the restricted diffusion technique of Equation 1 can be applied to electrolyte systems that have more than one relaxation time constant, with the general result including a distribution of time constants, as shown in Equation 2.

OCV(t_{fit})=k₀+∫_{fit|0}^{t}^{_{fit|final}}e^{-Γt}f(Γ)dΓ [2]

where τ=1/τ. In its continuous form, this is the Laplace inversion equation and applies to a distribution ranging from Γ=0 to Γ=∞. This is an ill-defined problem with infinite arbitrary solutions. However, it can be discretized (t_{fit|0}−t_{fit|final} is constrained) over a specified range of Γ and solved rigorously using algorithms such as Contin, maximum-entropy, or global minimization, with the end result related to the overall effect of all relaxation time constants in the system. Similar to Equation 1, k₀ is the value of OCV at equilibrium. The sum of all values of Γ in a discretized form of f(Γ) equals the initial voltage of the fitting region.

Equations 1 and 2 apply rigorously to model relaxation phenomena within the separator/electrolyte layer in a battery system. However, in addition to the electrolyte separator polarization/relaxation, batteries exhibit other relaxation phenomena, that include, but are not limited to, electrolyte relaxation within one or both electrodes, interfacial polarization/relaxation at one or both electrodes, relaxation of uneven distribution of electrode utilization in one or more dimensions, and internal heat generation in the cell. Equation 2 broadly captures these phenomena as well because they can be generally described as a superimposed series of exponential decays.

Equation 3, an extension of Equation 1, models transient voltage behavior in battery systems that can be described as a series of two exponentials

$$OCV ( {t}_{fit} ) = {k}_{0} + {k}_{1} {e}^{- \frac{t}{{τ}_{1}}} + {k}_{2} {e}^{- \frac{t}{{τ}_{2}}} \qquad [ 3 ]$$

where, k₂ and τ₂ are constants. In this scenario, the constant k₀ accounts for the cell equilibrium voltage at the present value of SOC; k₁ and k₂ indicate the magnitude of two relaxation phenomena, and τ₁ and τ₂ are time constants for two relaxation phenomena. The values of k₁/k₂ and τ₁/τ₂ must be sorted by sign and magnitude in order to compare values from fits to different data sets. A person with ordinary skill in the art would know how to handle this.

Typically, batteries operate under conditions of transient loads as well as transient environmental conditions. Thus, the condition in which a cell has been well-polarized and then is allowed to relax at OCV for long periods of time may be rarely, if ever, met. These conditions are desirable for the framework described for restricted diffusion experiments, but we demonstrate that short periods of stability, either under open-circuit or load conditions, are sufficient for capturing meaningful information with this method.

### Resting Cells

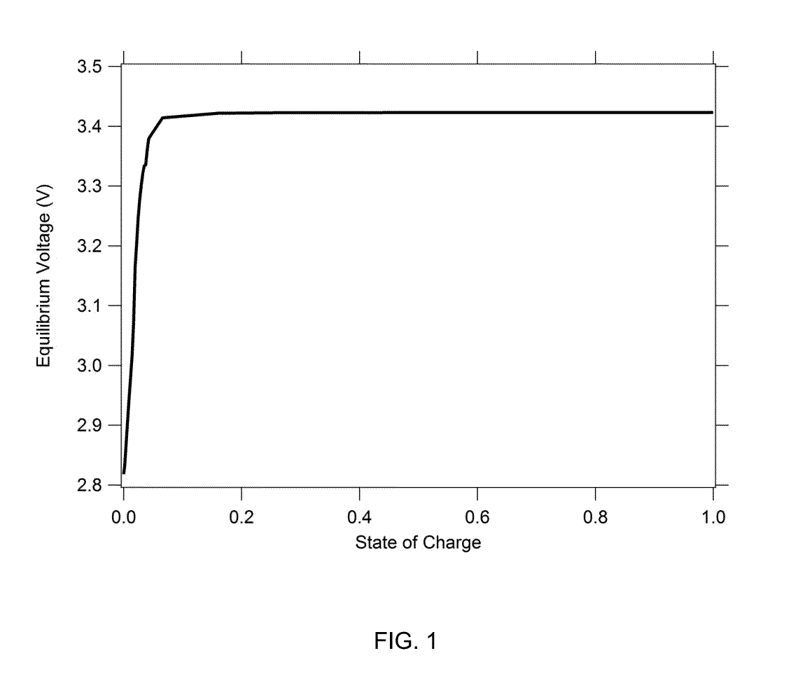

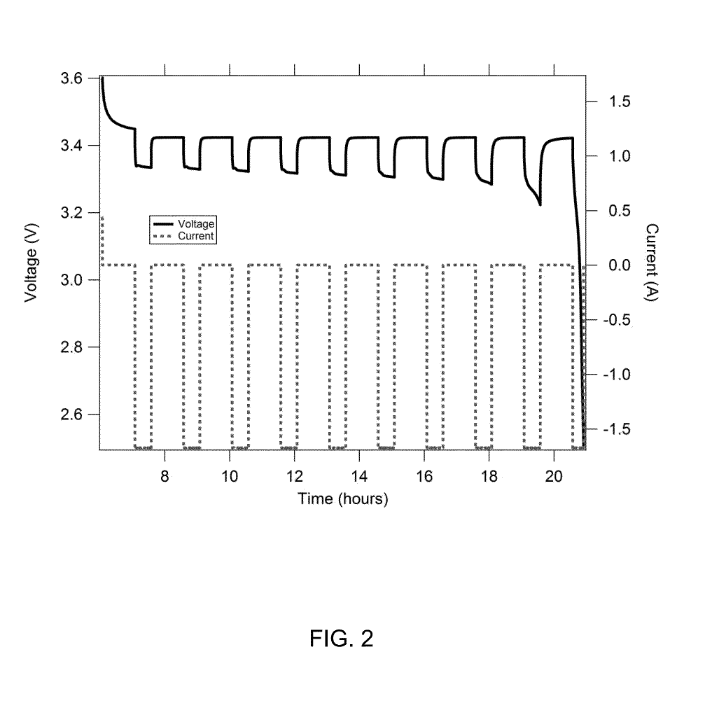

The voltage curve in FIG. 2 is from a battery cell that started from a fully-charged state and underwent a constant-current discharge for 0.5 hours. As the cell discharged, the voltage decreased from the OCV value of 3.42V to about 3.3V. In the initial region of the discharge, the cell has a flat curve of voltage vs. SOC, as shown in FIG. 1. During the periods when discharge currents are applied, the voltage decrease was caused by cell polarization processes described above. The discharge steps were stopped at increments of 10% of the total cell capacity, at which points the battery was allowed to rest for 1 hour periods. During these rest periods, the cell relaxed back towards its OCV value. The OCV values at each SOC point along the curve in FIG. 2 agree with the separately-determined OCV values in the equilibrium OCV vs SOC curve in FIG. 1.

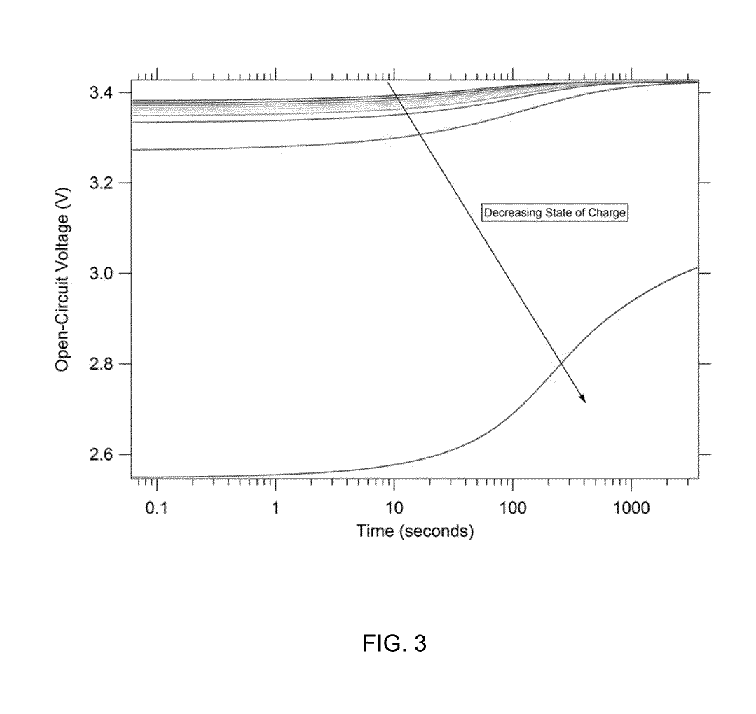

Data was extracted from the curve in FIG. 2, resulting in the OCV vs. time curves in FIG. 3. Each curve in FIG. 3 was individually fitted to a discretized form of Equation 2 using the Contin algorithm. The output of this fitting routine is the distribution function of time constants, f(Γ), along the range of 10⁻⁴ s<Γ<0.1 s. The distribution functions capture the relative contribution of relaxation time constants observed during the course of the OCV measurement. The distribution functions fit the curves in FIG. 3 closely across the entire time-scale and are not shown for clarity.

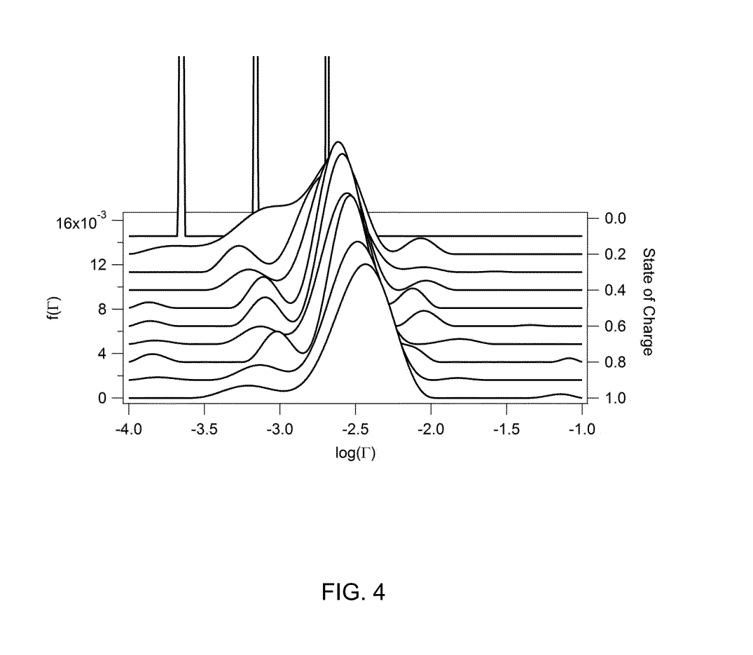

FIG. 4 is a series of relaxation curves that show distributions for f(Γ) for various SOCs. At each value of SOC, the relaxation curve has a unique fingerprint associated with it. The curves tend to have peaks that are relatively well-separated, making it possible to distinguish multiple concurrent relaxation processes. Concurrent relaxation processes that share the same value of Γ would appear as a relatively larger contribution to f(Γ). Concurrent relaxation processes that manifest as distributions of time constants and overlap in their range of Γ would appear as overlapping peaks. Because the time scale in FIG. 4 covers orders of magnitude, distinctly separated peaks must arise from distinct relaxation processes. The values of Γ in FIG. 4 are physically relevant to the physical and geometric properties of the battery system under study, with some timescales extending into hours. The fit function f(Γ) can, in principle, be estimated with information gained at much shorter timescales as long as the data is obtained with sufficient resolution. Thus, the relaxation time constants can be captured within tens of seconds, rather than minutes or hours. Although the characteristic fingerprints of f(Γ) change noticeably from 100 to 20% SOC, the curves at 10% and 0% SOC change dramatically, indicating a very strong signal in that regime.

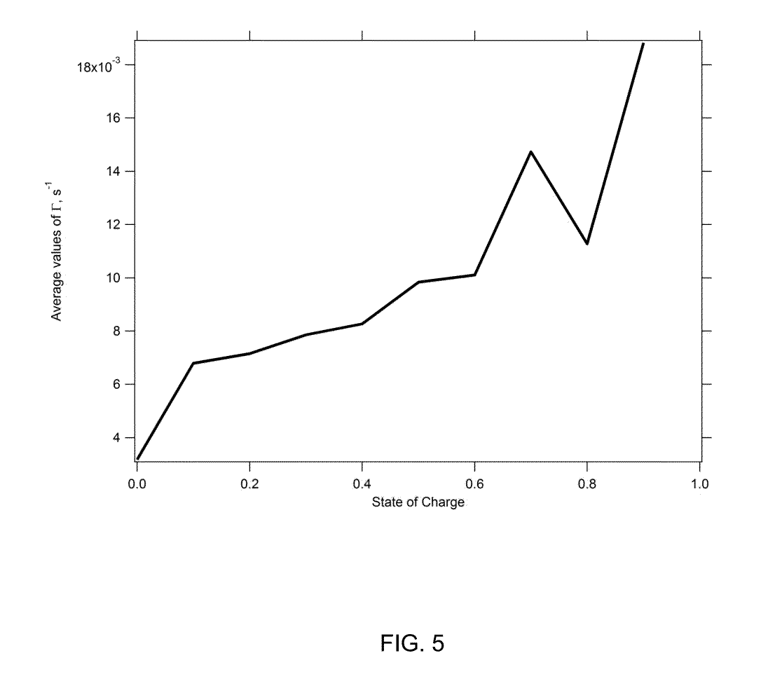

The distribution functions in FIG. 4 are clearly distinct. The distributions in FIG. 4 can be analyzed in numerous ways, including, but not limited to, finding peak centers, peak widths, and deconvolving overlapping peaks. A simple method of averaging the distributions in FIG. 4 was chosen. FIG. 5 is a plot of average time constants Γ_{average} from the distributions in FIG. 4 as a function of SOC, calculated using Equation 4.

$${Γ}_{average} = \frac{{\sum }_{i}^{ } f ( {T}_{i} ) {Γ}_{i}}{{\sum }_{i}^{ } f ( {Γ}_{i} )} \qquad [ 4 ]$$

where Γᵢ values are the discrete components of the fitted distribution function. Equation 3 is equivalent to the 1^{st}/0^{th} moments of the distribution, and calculating Γ_{average} in this manner weights the average by the magnitude of the contribution at each value of Γ. This calculation captures the average relaxation behavior across the entire fitted range. On average, the time constants decrease as the cell discharges more deeply, with the steepest slope at the deepest discharge states. The data in FIGS. 1 through 4 show that a cell's relaxation curve can provide information related to its SOC, thus validating this method.

The experiment whose results are shown in FIG. 2 was designed to capture relaxation curves at various values of SOC. Those curves were individually extracted as shown in FIG. 3 and fitted using Equation 2. The fit results gave distribution functions that indicated that the cell had unique relaxation behavior at each value of SOC, but the distribution functions were difficult to correlate directly to SOC.

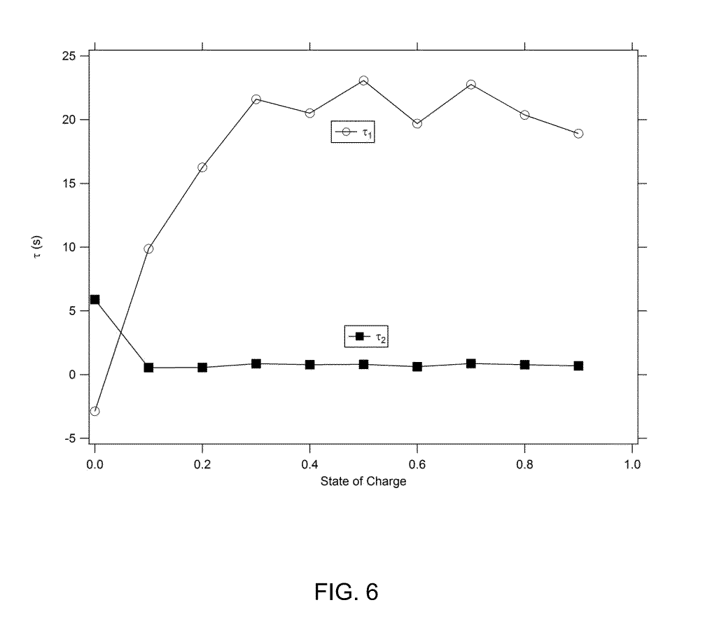

Detailed distribution function fitting and analysis, as described in the generation of FIGS. 3 and 4, requires long relaxation times and intensive computational power. This method may be difficult to implement efficiently with current embedded computer hardware and with realistic real-world rest periods. But a simple approach was found. The first 10 s of the relaxation curves in FIG. 3 were fit with a double-exponential decay, using an implementation of the Levenberg-Marquardt algorithm, in order to extract the relaxation time constants τ₁ and τ₂. FIG. 6 shows a plot of the relaxation time constants as a function of SOC. In FIG. 6, τ₂ has a small value that remains relatively constant across the cell's DOD range. Without wishing to be bound to any particular theory, it may be that τ₁ corresponds to the initial depolarization of the electrochemical interfaces within the cell. In FIG. 6, τ₁ is also relatively small compared to the relaxation processes that are detected during long rest steps, but it provides a value that is sensitive (i.e., has a steep slope) to the cell's SOC at deep discharge states. Thus, such a simple fitting algorithm and a rest period on the order of seconds may be sufficient to detect useful information about a cell's changing SOC as the cell cycles. It is not only feasible to include such short rest periods in real-world battery cell operating conditions, but there are many operating scenarios where such short rest periods occur during normal operation.

### Resting Cells

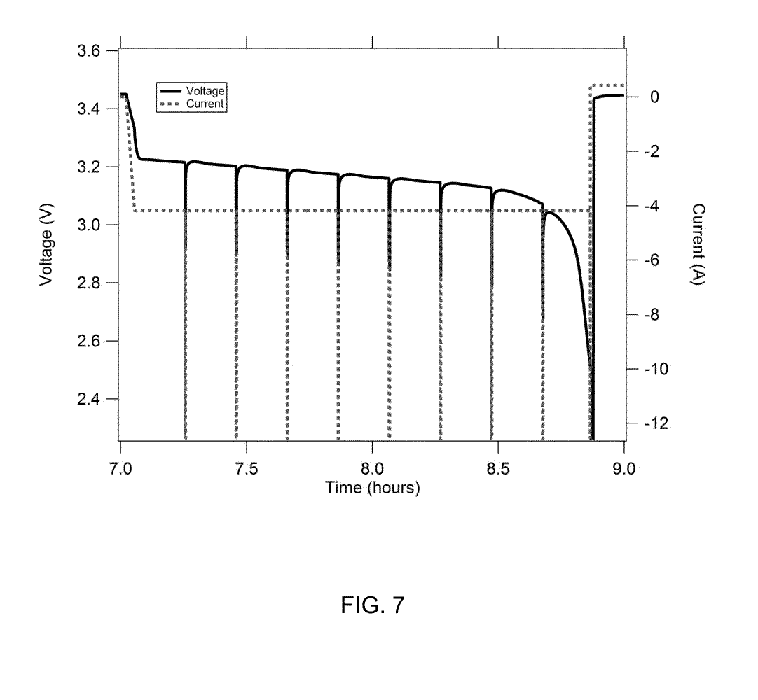

The preceding discussion has been for scenarios in which short rest periods can be incorporated into the cycling of a cell. But, it would be even more useful to find a way to determine SOC without rest periods. For example, an electric car battery has a long duty cycle during a road trip, and it is important to monitor the battery's SOC at various times during that trip. During city driving, there are many opportunities for rest periods, such as at stoplights. But on a long road trip, a car may run for hours without stopping at all. Introducing rest periods into a long road trip would not be at all desirable. However, there are nearly constant changes in the load even during such a trip. For example, the load on the battery increases when accelerating or when going up a hill. A hypothetical example of such a duty cycle is shown in FIG. 7 in a plot of voltage as a function of time. In FIG. 7, a cell undergoes a steady discharge with periodic high-current spikes whenever its capacity is reduced by about 10%. For a continuously discharging cell, each change in the applied current results in increased (decreased) polarization of the cell when the current increases (decreases).

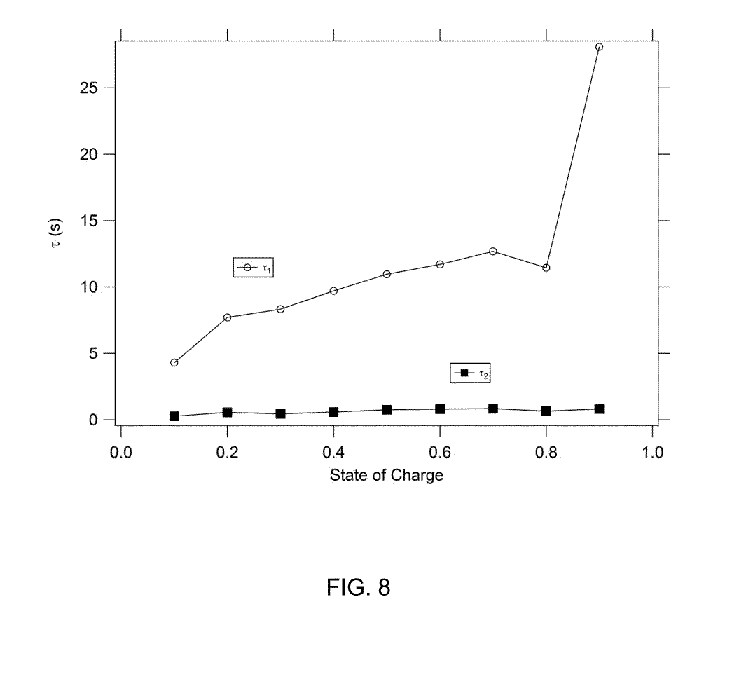

With the same double-exponential fit used to generate FIG. 6, voltage depolarization curves were fit to the first 10 s after the current returned to the baseline value around negative 4 Amps. There is no fully discharged state here because, at the end of the final pulse, the cell returns to a rest state rather than a lower discharge state. The resulting time constants are shown in FIG. 8.

The first 10 seconds after the current returned to the baseline values of the curves in FIG. 7 were fit with a double-exponential decay, using an implementation of the Levenberg-Marquardt algorithm, as was described above for FIG. 5. There is no fully discharged state here because, at the end of the final pulse, the cell returns to a rest state rather than a lower discharge state. FIG. 8 shows a plot of the relaxation time constants as a function of SOC. In FIG. 8, τ₂ has a very small value that remains relatively constant across the cell's SOC range. In FIG. 6, τₜ is also relatively small compared to the relaxation processes that are detected during long rest steps, but it provides a value that is sensitive (i.e., has a steep slope) to the cell's SOC at many discharge states. Thus, such a simple fitting algorithm can also be used to determine SOC even without rest periods.

This example used a current with a magnitude of 4 Amps for a cell with a capacity of approximately 8 Amp-hours. Charge and discharge rates are routinely expressed relative to the rate at which a cell would be fully charged or discharged in a period of 1 hour. The term for this ratio is C-rate, and is typically expressed as C. Thus, for an 8 Amp-hour cell, a charge or discharge current of 8 Amps would be 1 C. In the example above, the 4 Amp discharge corresponds to C/2. In principle, this method would apply at much lower C-rates.

These results show that τ₁ has a relatively strong dependency on SOC. Interestingly, this τ₁ is most sensitive to SOC near the fully charged state—just the opposite of the dependency of the τ₁ in the rest case (FIG. 6), which is most sensitive to SOC near the fully discharged state. Furthermore, the τₐ in FIG. 8 is more sensitive across the entire SOC range than the τ₁ in FIG. 6, suggesting that dynamic usage scenario can give even more useful SOC information. The magnitudes of the time constants are similar in FIGS. 5 and 7, which suggests that the same physical relaxation processes are at work in each usage scenario (depolarizing from a load state to a rest state versus depolarizing from a high-load state to a lower-load state).

The curves of time constants vs. SOC shown in FIGS. 5 and 7 would serve as a database for future analysis of relaxation data. These experiments, and others in which controlled charge or discharge sequences are performed, could be used to populate one or more tables of data. This data would be stored and referenced upon command. For example, if this fitting method were performed in real time on an operating cell, the resultant fit parameters could be compared to stored, previously-generated data in order to get an estimate of the cell's SOC. It is logical to assume that transient voltage responses under load would give different fit results depending on the current sign and magnitude. Thus, there is additional value in having richly-populated tables in which numerous experimental conditions were tested, fitted and analyzed prior to a cell's installation for long-term usage. Furthermore, the cell response behavior may change over the course of the cell's lifetime as aging and other effects occur. To that end, the database may be periodically replenished. For example, the initial experiments used to build the database could be repeated periodically as a cell ages.

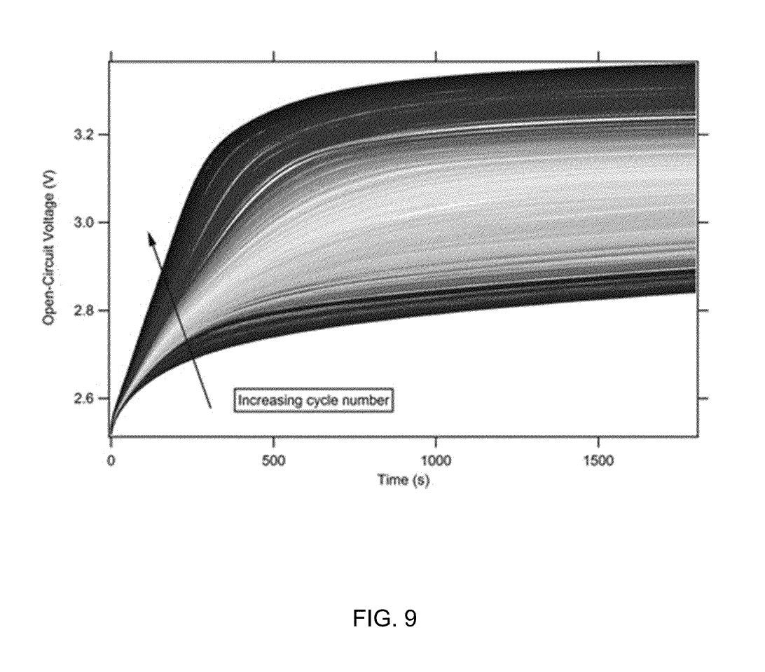

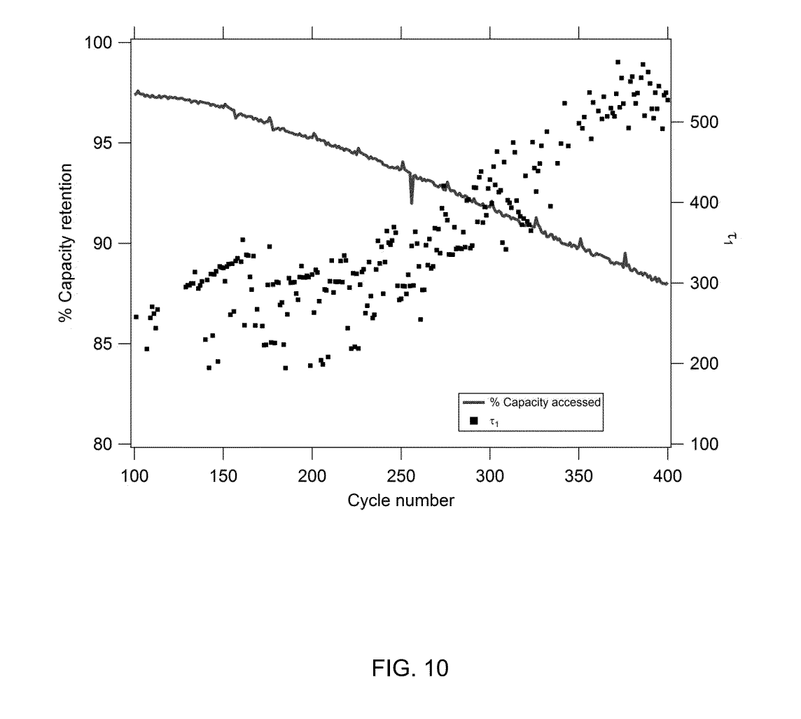

The relaxation processes that indicate a cell's state-of-charge are sensitive to the processes happening in the cell's active material—these processes may be occurring either within active particles, at active particle surfaces, or between active particles in a composite electrode. The physical and chemical characteristics that give rise to these processes may change over the lifetime of a cell due to chemical reactions, physical redistribution of materials, etc. Thus one would expect that relaxation time constants for these processes would change as a cell ages due to changes in transport properties, impedances, diffusion barriers and length-scales. FIG. 9 shows relaxation curves following nearly 500 deep-discharge cycles for a battery. The shape of the relaxation curves changes substantially over this number of cycles, with the relaxation proceeding progressively faster at the later cycle numbers. Relaxation time constants for fits to the first 100 seconds of each curve are shown in FIG. 10.

The time constants in FIG. 10 show sensitivity of the time constants to the capacity fade process happening in the first 50 cycles (the capacity access dips, and the time constants show an inverse peak). The time constants also show sensitivity to the slower capacity fade process happening between 100-400 cycles. In this region, the larger time constants increase from around 200 to around 500 seconds.

These time constants can be tracked at the end of every duty cycle while the battery rests before charging. Given the results described above for battery SOC monitoring via time constant determination, it is likely that SOH information could be determined under a variety of scenarios, including changing load scenarios.

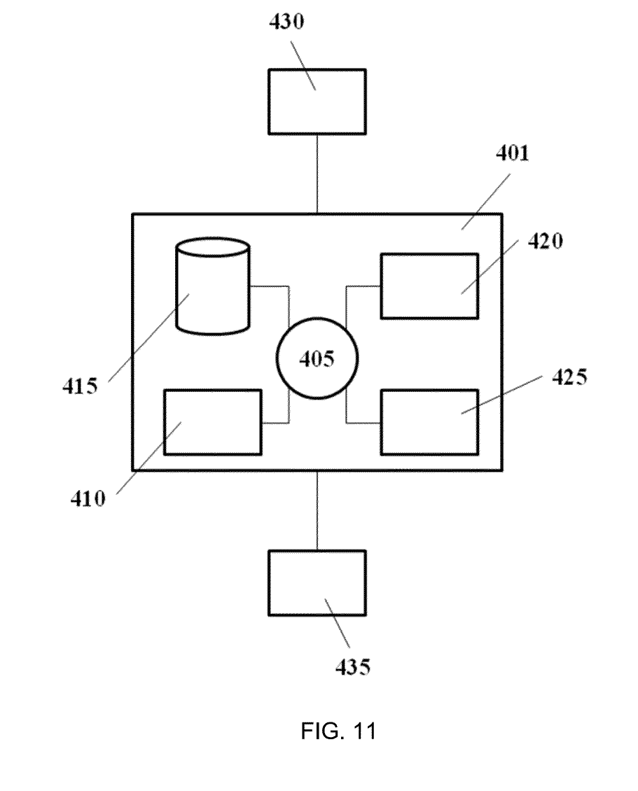

Methods of the present disclosure, including applications of algorithms for determining battery state of charge, can be implemented with the aid of computer systems. FIG. 11 shows a computer system 401 that is programmed or otherwise configured to determine the state of charge of a battery. The system 401 includes a central processing unit (CPU, also “processor” and “computer processor” herein) 405, which can be a single core or multi core processor, or a plurality of processors for parallel processing. The system 401 also includes computer memory 410 (e.g., random-access memory, read-only memory, flash memory), electronic data storage unit 415 (e.g., hard disk), communication interface 420 (e.g., network adapter) for communicating with one or more other systems and/or components (e.g., batteries), and peripheral devices 425, such as cache, other memory, data storage and/or electronic display adapters. The memory (or memory location) 410, storage unit 415, interface 420 and peripheral devices 425 are in communication with the CPU 405 through a communication bus (solid lines), such as a motherboard. The storage unit 415 can be a data storage unit (or data repository) for storing data.

In some situations, the computer system 401 includes a single computer system. In other situations, the computer system 401 includes multiple computer systems in communication with one another, such as by direct connection or through an intranet and/or the Internet.

Methods as described herein can be implemented by way of machine (or computer processor) executable code (or software) stored on an electronic storage location of the system 401, such as, for example, on the memory 410 or electronic storage unit 415. During use, the code can be executed by the processor 405. In some cases, the code can be retrieved from the storage unit 415 and stored on the memory 410 for ready access by the processor 405. As an alternative, the electronic storage unit 415 can be precluded, and machine-executable instructions can be stored in memory 410. The code can be pre-compiled and configured for use with a machine have a processer adapted to execute the code, or can be compiled during runtime. The code can be supplied in a programming language that can be selected to enable the code to execute in a pre-compiled or as-compiled fashion.

The system 401 can include or be coupled to an electronic display 430 for displaying the state of charge and/or state of health of one or more batteries. The electronic display can be configured to provide a user interface for providing the state of charge and/or state of health of the one or more batteries. An example of a user interface is a graphical user interface. As an alternative, the system 401 can include or be coupled to an indicator for providing the state of charge and/or state of health of one or more batteries, such as a visual indicator. A visual indicator can include a lighting device or a plurality of lighting devices, such as a light emitting diode, or other visual indicator that displays the state of charge of a battery (e.g., 10%, 20%, 30%, 40%, 50%, 60%, 70%, 80%, or 90% of maximum charge). Another example of an indicator is an audible indicator or a combination of visual and audible indicators.

The system 401 can be coupled to one or more batteries 435. The system 401 can execute machine executable code to implement any of the methods provided herein for determining the state of charge of the one or more batteries 435.

Aspects of the methods and systems provided herein, such as methods for determining the state of charge of a battery, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A method of determining the state of charge for a battery cell comprising:
measuring voltage and current as a function of time while the battery cell is operating;
recording in a memory location the voltage as a function of time over periods in which the current, expressed in terms of C-rate, is stable to within +/−0.01 C;
fitting, using a computer processor, the recorded voltage as a function of time to a pre-defined function that has three or more fit parameters, wherein the three or more fit parameters are selected to generate a fit of the recorded voltage as a function of time; and
determining the state of charge of the battery cell by comparing, using a computer processor, the three or more fit parameters to a previously-populated look-up table in a memory location, wherein the look-up table correlates the fit parameters to state-of-charge values.

2. The method of claim 1 wherein the battery cell comprises lithium metal as an anode, lithium iron phosphate as a cathode, and a polymer electrolyte as a separator.

3. The method of claim 1 wherein the pre-defined function has a single exponential term and has the form.
$$OCV ( {t}_{fit} ) = {k}_{0} + {k}_{1} {e}^{- \frac{t}{{τ}_{1}}}$$

4. The method of claim 1 wherein the pre-defined function has two exponential terms and has the form:
$$OCV ( {t}_{fit} ) = {k}_{0} + {k}_{1} {e}^{- \frac{t}{{τ}_{1}}} + {k}_{2} {e}^{- \frac{t}{{τ}_{2}}}$$

5. The method of claim 1 wherein the method is performed in real time on an operating battery.

6. A computer-readable medium comprising code which, upon execution by a computer processor implements a method, the method comprising:
measuring voltage and current as a function of time while the battery cell is operating;
recording in a memory location the voltage as a function of time over periods in which the current, expressed in terms of C-rate, is stable to within +/−0.01 C;
fitting, using a computer processor, the recorded voltage as a function of time to a pre-defined function that has three or more fit parameters, wherein the three or more fit parameters are selected to generate a fit of the recorded voltage as a function of time; and
determining the state of charge of the battery cell by comparing, using a computer processor, the three or more fit parameters to a previously-populated look-up table in a memory location, wherein the look-up table correlates the fit parameters to state-of-charge values.

7. The computer-readable medium of claim 6 wherein the battery cell comprises lithium metal as an anode, lithium iron phosphate as a cathode, and a polymer electrolyte as a separator.

8. The computer-readable medium of claim 6 wherein the pre-defined function has a single exponential term and has the form.
$$OCV ( {t}_{fit} ) = {k}_{0} + {k}_{1} {e}^{- \frac{t}{{τ}_{1}}}$$

9. The computer-readable medium of claim 6 wherein the pre-defined function has two exponential terms and has the form:
$$OCV ( {t}_{fit} ) = {k}_{0} + {k}_{1} {e}^{- \frac{t}{{τ}_{1}}} + {k}_{2} {e}^{- \frac{t}{{τ}_{2}}}$$

10. The computer-readable medium of claim 6 wherein the method is performed in real time on an operating battery.
